(19) United States
(12) Patent Application Publication
(10) Pub. No.: US 2009/0090997 A1
(43) Pub. Date: Apr. 9, 2009

(54) SOLID ELECTROLYTIC CAPACITOR ELEMENT AND PRODUCTION METHOD THEREOF

(75) Inventors: Kazumi Naito, Chiba (JP); Katutoshi Tamura, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku,TOKYO (JP)

(21) Appl. No.: 11/994,381

(22) PCT Filed: Jun. 30, 2006
(86) PCT No.: PCT/JP2006/313089

§ 371 Date: Dec. 31, 2007

(30) Foreign Application Priority Data
Jun. 30, 2005 (JP) 2005-191228

(51) Int. Cl. H01L 21/20; H01G 9/15

(52) U.S. Cl. 257/532; 438/381; 257/E21.09

(57) ABSTRACT

The present invention relates to a production method of solid electrolytic capacitor element, comprising a step of forming a semiconductor layer on a surface of a conductor having a dielectric oxide film thereon and having an anode lead connected thereto by conducting electrolytic oxidation-polymerization using pyrrole dimer at around room temperature, a solid electrolytic capacitor element produced by the method, solid electrolytic capacitor using the element and uses thereof. According to the invention, low-temperature polymerizability of pyrrole, which is inexpensive, can be suppressed, whereby the invention enables production of solid electrolytic capacitor elements having a semiconductor layer formed in industrially advantageous manner.

### TECHNICAL FIELD

The present invention relates to a production method of solid electrolytic capacitor element, comprising forming an organic semiconductor layer containing polypyrrole as its main component. More specifically, the invention relates to a production method of solid electrolytic capacitor element, comprising a step of forming an organic semiconductor layer by immersing a conductor having a dielectric oxide film thereon in a solution containing pyrrole dimer to conduct electrolytic polymerization at around room temperature, a solid electrolytic capacitor element produced by the method, solid electrolytic capacitor using the element and uses thereof.

### BACKGROUND ART

As capacitors having high capacitance and relatively low ESR value which are used in various electronic devices, aluminium solid electrolytic capacitor and tantalum solid electrolytic capacitor are known.

A solid electrolytic capacitor is produced by encapsulating solid electrolytic capacitor element(s) constituted by an aluminium foil having fine pores on the surface or a sintered body of tantalum powder having fine pores in its inside as one electrode (conductor), a dielectric layer formed on the electrode surface, the other electrode (generally, a semiconductive layer) formed on the dielectric layer and an electrode layer formed on said other electrode layer.

Recently, since a solid electrolytic capacitor are required to have a low ESR (equivalent series resistance), an electroconductive polymer is always employed as inside semiconductor layer. Such a semiconductor layer is formed by chemical polymerization or electrolytic polymerization method. However, semiconductor layers formed by conventional chemical polymerization method are not uniform in thickness, composition and continuity (for example, branches exist in the polymer), as compared with those obtained by electrolytic polymerization method. Such a semiconductor has a high resistance because of its non-uniformity and other reasons. As a result, the ESR (equivalent series resistance) value of a produced capacitor tends to be high. Therefore, electrolytic polymerization method is preferred.

One example of electrolytically polymerizing a sintered body as a conductor having an anode lead connected thereto is a method where a sintered body having been subjected to treatments up to forming a dielectric layer thereon is immersed in a separately-prepared solution for forming a semiconductor layer thereon except for part of the anode lead and a voltage is applied between the sintered body and a cathode plate provided in the solution to thereby form a semiconductor layer. Electrolytic polymerization methods are categorized into two types: one is a method where the sintered body is used as anode; and the other is where an external electrode placed in the vicinity of the sintered body is used as anode.

As monomer used in forming a semiconductor layer for solid electrolytic capacitor using an electroconductive polymer as semiconductor layer, two kinds of monomers, pyrrole and 3,4-ethylenedioxythiophene, are widely used. The former is inexpensive, however, as described that polymerization is carried out at a temperature of −25 to −45° C. in Japanese Patent Application Laid-Open No. S62-189714 (Patent Document 1), since polymerization rate of the monomer is high, polymerization needs to be carried out at a low temperature. Generally, in a case where a semiconductor layer is formed through electrolytic polymerization by using pyrrole monomer, the polymerization must be carried out at a low temperature of 5° C. or lower. If the temperature exceeds 5° C., polymers formed on the surface of micropores cover in the micropores and further polymerization cannot proceed inside the micropores, which results in producing a capacitor with low capacitance.

3,4-ethylenedioxythiophene has a large molecular weight as compared with pyrrole monomer and its polymerization rate is low. Therefore, the monomer can be polymerized at room temperature to form a semiconductor layer. However, it is disadvantageous in that the raw material monomer is expensive.

[Patent Document 1] Japanese Patent Application Laid-Open No. S62-189714 (Patent Document 1)

### DISCLOSURE OF INVENTION

### Problems to be Solved by Invention

The object of the present invention is to provide a method of producing a solid electrolytic capacitor element, comprising formation of semiconductor layer at around room temperature which is industrially advantageous by using pyrrole which is inexpensive and controlling the high polymerization rate (low-temperature polymerizability).

### Means for Solving the Problem

As a result of intensive studies to solve the above-described problem, the present inventors have found that in a production method of solid electrolytic capacitor element where a semiconductor layer and then an electrode layer is formed on a conductor having a dielectric oxide film formed on the surface, electrolytic polymerization can proceed at a rate controllable at around room temperature by using pyrrole dimer instead of conventional pyrrole, to thereby form a semiconductor layer, and thus completed the present invention.

That is, the present invention relates to a method for producing a solid electrolytic capacitor element, solid electrolytic capacitor using the element and uses thereof.

1. A method for producing a solid electrolytic capacitor element, comprising electrolytically oxidation-polymerizing pyrrole dimer to form a semiconductor layer on a conductor having dielectric oxide film thereon.
2. The method for producing a solid electrolytic capacitor element according to 1, wherein the semiconductor is an organic semiconductor mainly consisting of polypyrrole doped with a dopant.
3. The method for producing a solid electrolytic capacitor element according to 2, wherein the dopant is at least one kind selected from aryl sulfonic acid compounds and salts thereof, alkyl sulfonic acid compounds and salts thereof, various polymeric sulfonic acid compounds and salts thereof and a compound in which each of these sulfonic acid compounds is substituted by various substituents.
4. The method for producing a solid electrolytic capacitor element according to 1, wherein the polymerization temperature is within a range of 10 to 40° C.
5. The method for producing a solid electrolytic capacitor element according to 1, wherein as the pyrrole dimer, a reaction product isolated from a reaction solution obtained by allowing a solution containing pyrrole and an oxidant in water or a mixed solvent of an organic solvent and water to react at 10 to 100° C. for 1 minute to 1600 hours is used.
6. The method for producing a solid electrolytic capacitor element according to 1, wherein the conductor is a metal or alloy consisting mainly of at least one selected from the group consisting of tantalum, niobium, titanium and aluminium, niobium oxide, or a mixture of two or more of these metals, alloys and niobium oxide.
7. The method for producing a solid electrolytic capacitor element according to 1, wherein the conductor consists of tantalum having a CV value of 80,000 μF·V/g or more.
8. The method for producing a solid electrolytic capacitor element according to 1, wherein the conductor consists of niobium having a CV value of 150,000 μF·V/g or more.
9. The method for producing a solid electrolytic capacitor element according to any one of 1 to 8, wherein the conductor consists of a sintered body having an anode lead connected thereto.
10. The method for producing a solid electrolytic capacitor element according to 9, wherein material of the anode lead is tantalum, aluminium, niobium, titanium, or an alloy mainly consisting of these valve-action metals.
11. The method for producing a solid electrolytic capacitor element according to 9, wherein the anode lead is in form of wire, foil or sheet.
12. The method for producing a solid electrolytic capacitor element according to 2, wherein electroconductivity of the semiconductor is within a range of 10⁻² to 10³ S/cm.
13. A solid electrolytic capacitor element produced by the method described in any one of 1 to 12.
14. A solid electrolytic capacitor obtained by encapsulating the solid electrolytic capacitor element described in 13 with jacketing resin.
15. An electronic circuit using the solid electrolytic capacitor described in 14.
16. An electronic device using the solid electrolytic capacitor described in 14.

### EFFECT OF INVENTION

Specifically, the present invention provides a method of producing a solid electrolytic capacitor element, characterized in that, in a method of producing a solid electrolytic capacitor element comprising sequentially stacking a dielectric oxide film, a semiconductor layer and an electrode layer on a conductor, the semiconductor layer is formed through electrolytic polymerization using pyrrole dimer at around room temperature. According to the present invention, a solid electrolytic capacitor element having an excellent ESR value can be produced by an industrially advantageous manner.

### BEST MODE FOR CARRYING OUT THE INVENTION

One embodiment of the method of producing a solid electrolytic capacitor element and solid electrolytic capacitor produced thereby according to the present invention is described below.

In the solid electrolytic capacitor element of the present invention, a dielectric oxide film, a semiconductor layer and an electrode layer are sequentially stacked on a sintered body consisting of conductive powder of valve-action metal.

Preferred examples of material for conductor used in the present invention include tantalum, niobium, alloy powders containing these metals as main components, sintered bodies having many micropores inside obtained by molding and sintering powder of niobium monoxide or the like, and aluminium foil having an etched surface. Here, the term “main component” means a component which accounts for 50 mass % of the material.

If a sintered body is prepared by using a powder having a small particle size, the produced sintered body can have a large specific surface area per mass. The method of the present invention is effective in manufacturing a capacitor using such a sintered body as its conductor. For example, in case of using a sintered body having a high CV value (=product of capacitance and chemical formation voltage measured in electrolysis solution) (a high specific surface area) such as a sintered body of a tantalum powder having a CV value of 80,000 μF·V/g or more and a sintered body of a niobium powder or niobium monoxide powder having a CV value of 150,000 μF·V/g or more, when the size is 5 mm³ or more, the method of the present invention is particularly effective.

An outgoing lead can be connected directly to the conductor. In a case where powdery conductor is molded or sintered after molded, a part of a separately-prepared outgoing lead may be molded together with the conductor at the time of molding the conductor and thus the other part of the outgoing lead outside the molded body may be used as outgoing lead of one electrode in the capacitor.

The anode lead may have either form of wire, foil or sheet. Also, the anode lead may be connected to the sintered body after sintering, instead of implanting the anode lead in the molded body before sintering. Examples of the material for the anode lead include tantalum, aluminium, niobium, titanium and alloys mainly containing these valve-action metals. Moreover, the anode lead may be used after subjecting a part thereof to at least one treatment selected from carbonization, phosphidation, boronation, nitridation, sulfidation and oxidation.

In a case where the anode lead is implanted in the molded body, it is preferable that the implantation depth of the anode lead in the sintered body be one-third or more of the sintered body's length in the implanting direction, more preferably two-thirds or more, in consideration for maintaining strength of the sintered body to endure the thermal and physical pressures at the time of encapsulating the capacitor element which is described later.

In order to prevent short circuit caused by semiconductor layer attaching to the upper portion of the anode lead when the conductor has an anode lead or to the anode part when part of the conductor serves as anode, insulative resin may be used to cover the boundary region (on the anode lead side or on the anode part side) between the sintered body and the anode lead or the anode part in a belt-like manner, so that insulation can be ensured.

In the present invention, a dielectric oxide film layer is formed on a part of surface of or the whole surface of the conductor and the anode lead or the anode part. Examples of dielectric oxide film layer include dielectric layers containing as main component at least one selected from metal oxides such as Ta₂O₅, Al₂O₃, TiO₂ and Nb₂O₅. The dielectric layer can be obtained by chemically forming the anode substrate in an electrolysis solution. Alternatively, the layer may be a dielectric layer comprising a mixture of a dielectric layer mainly containing at least one metal oxide and a dielectric layer used in a ceramic capacitor (International Publication No. WO00/75943 pamphlet (U.S. Pat. No. 6,430,026)).

The present invention is characterized in that a semiconductor layer mainly containing polypyrrole is formed on the dielectric layer by subjecting pyrrole dimer to oxidation polymerization in stead of using pyrrole monomer conventionally used.

As pyrrole dimers, there are isomeric forms, namely, those are each formed by two pyrrole molecules bonded to each other between 2-positions, bonded between 2-position and 3-position and bonded between 3-positions. Also, stereoisomeric forms of these exist. There is no particular limitation on structure of pyrrole dimer used in the present invention. Generally, mixture of the above-described isomeric forms is used.

There is no particular limitation on production method of pyrrole dimer. For example, pyrrole dimer can be prepared by the following method. That is, after dissolving pyrrole in a mixed solvent of water and ethanol, an oxidant (such as iron toluenesulfonate, toluene sulfonic acid, and iron naphthalenesulfonate) is added thereto. By allowing reaction to proceed therein at 10 to 100° C. for 1 minute to 1600 hours, the resulted solution is obtained in a blackened state. Ethanol is distilled off from the solution, and a water layer and an oil layer are separated from each other. By removing monomers and polymers comprising three or monomer units from the oil layer by liquid chromatography, pyrrole dimers can be obtained. Structure of the obtained pyrrole dimers can be confirmed by NMR analysis and mass spectrum analysis.

A method of forming a semiconductor layer from pyrrole dimer through electrolytic oxidation polymerization method can be conducted in the almost same manner as in a conventional method of electrolytic oxidation polymerization using pyrrole monomers which is conducted at 5° C. or lower, except that the temperature is set to be around room temperature (10 to 35° C.) instead of 5° C. or lower.

One example of the method is a method where a semiconductor is formed by repeating twice or more a step of immersing a sintered body of valve-action metal having dielectric oxide film formed thereon and an anode lead connected thereto in a solution containing pyrrole dimer and dopant and applying electric current thereto to thereby form a semiconductor layer and a subsequent step of pulling the sintered body out from the solution, followed by washing and drying, further immersing the sintered body in a solution for chemical reformation containing electrolyte (inorganic acid, organic acid or salts thereof) to thereby carry out chemical reformation by applying current and pulling the sintered body out from the solution, followed by washing and drying.

The semiconductor layer thus formed contains as its main component a charged electroconductive polymer obtained by doping a dopant to polypyrrole having a repeating unit of pyrrole structure derived from pyrrole dimer as raw material.

As the dopant, at least one of known dopants such as aryl sulfonic acid compounds and salts thereof, alkyl sulfonic acid compounds and salts thereof, various polymeric sulfonic acid compounds and salts thereof and compounds in which the above described sulfonic acids have various substituents is used.

In the present invention, by using pyrrole dimer as starting material, polymerization rate can be lowered as compared with conventional method using pyrrole monomer, so that the polymerization can proceed at an appropriate rate even at room temperature to form a semiconductor layer and a capacitor having a good capacitance can be obtained. The method of the present invention is suitable in a case where a semiconductor layer is to be formed on a conductor having particularly small micropores and a large volume (a conductor having a large CV value).

In the present invention, by applying a predetermined amount of constant direct current for a predetermined period of time, a semiconductor layer is formed. According to this method, it is possible that the value obtained by dividing the standard deviation of capacitance values of a group of produced capacitors by the average value of capacitance can be 10% or less, preferably 7% or less, more preferably 5% or less. By applying a predetermined amount of constant direct current, the amount of current to be applied on each conductor is determined. Even if the amount of current applied to some of the conductors fluctuates for some reason, since the total amount is always constant, the current amount applied to the other conductors changes to offset the fluctuation. As a result, current supply to each conductor can be stable all through the current-applying time. The mass of the semiconductor layer is given by integration value of the total current amount and time if no side-reaction occurs. Therefore, the capacitance of capacitor which has a proportional relationship with the mass of the semiconductor layer can be stable and the standard deviation of capacitance values of a group of produced capacitors can be small. On the other hand, in conventional method where current is applied at constant voltage for a predetermined period of time to thereby form a semiconductor, current value supplied to each conductor is never stabilized all through the current-applying time and as a result, there is little possibility that the standard deviation of capacitance values of a group of produced capacitors can be small.

In the present invention, time for applying current and constant current value to be predetermined, which vary depending on the kind, size and density of the conductor used, the kind and thickness of the dielectric layer formed thereon, the kind of the semiconductor layer formed thereon and the like, are determined by conducting preliminary experiments. As one approach for preliminary experiment, properness of constant current values can be determined by controlling the mass of the semiconductor layer. For example, with each predetermined constant current value, time for applying current and the mass of semiconductor are plotted. In the plotted data, the current value with which the mass of semiconductor having reached saturation is the largest can be employed as the constant current value.

In the present invention, after applying a predetermined constant current, for the purpose of mending minute defects of dielectric layer caused by formation of the semiconductor layer, chemical formation may be conducted again (or in a case where formation of the dielectric layer is not conducted by chemical formation, chemical formation may be conducted for the first time). The operation of applying a predetermined current and conducting chemical formation may be repeated twice or more. Also, the constant current value may be changed in each operation repeated. Generally, when applying the constant current is stopped, the conductor is pulled up from the semiconductor layer-forming solution, washed and dried and then, chemical formation is allowed to be conducted again. Or the step of applying a constant current may be conducted once or more before starting the chemical reformation. Although the reason is not clear, the mass of the semiconductor is increased in a case where current is stopped once or more and then a step of washing and drying step is conducted between the repeated steps of applying current, as compared to a case where current is continuously applied, if the total time for applying current is the same in both of the cases.

Chemical reformation can be conducted in the same manner as in formation of dielectric layer by chemical formation as descried previously. The voltage employed in chemical reformation is generally the voltage value used in (the first) chemical formation or lower.

In the present invention, an electrode layer is formed on the semiconductor layer formed by the above-described method. The electrode layer can be formed, for example, by solidification of an electrically conducting paste, plating, metal deposition or attaching a heat-resistant electrically conductive resin film. Preferred examples of the electrically conducting paste include silver paste, copper paste, aluminum paste, carbon paste and nickel paste. One of these may be used or two or more thereof may be used. In the case of using two or more pastes, these pastes may be mixed or stacked as separate layers. The electrically conducting paste applied is then left standing in air or heated to thereby be solidified. The thickness of one electroconductive paste layer after solidified is generally about 0.1 to about 200 μm.

Generally, an electroconductive paste contains 40 to 97 mass % of electroconductive powder. If the content is less than 40 mass %, the conductivity of the prepared electroconductive paste is low. If the content exceeds 97 mass %, adhesiveness of the prepared electroconductive paste is low. An electroconductive paste in a mixture with electroconductive polymer or metal oxide powder as previously described as usable for forming the semiconductor layer may be used.

Examples of the plating include nickel plating, copper plating, silver plating, gold plating and aluminum plating. Examples of the metal to be deposited include aluminum, nickel, copper, gold and silver.

Specifically, the electrode layer is formed by sequentially stacking, for example, a carbon paste and a silver paste on the conductor having a semiconductor layer formed thereon.

Thus a solid electrolytic capacitor element having the layers up to the electrode layer stacked to form a cathode part is produced.

The solid electrolytic capacitor element of the present invention having such a structure is jacketed, for example, by resin mold, resin case, metallic jacket case, resin dipping or laminate film, whereby a solid electrolytic capacitor product for various uses can be completed. Among these, a chip-type solid electrolytic capacitor jacketed by resin mold is most preferred, in that reduction in the size and cost can be easily achieved.

With respect to the resin used for resin mold jacketing, a known resin used for encapsulation of a capacitor, such as epoxy resin, phenol resin and alkyd resin, can be employed. In all of these resins, when a low-stress resin generally available on the market is used, the encapsulation stress imposed on the capacitor element, which is generated at the time of encapsulation, can be mitigated and this is preferred. For encapsulation with resin, a transfer machine is used with preference.

The thus-produced solid electrolytic capacitor may be subjected to an aging treatment so as to repair the thermal and/or physical deterioration of the dielectric layer, which has been caused at the time of formation of electrode layer or at the time of jacketing. The aging treatment is performed by applying a predetermined voltage (usually, within twice the rated voltage) to the capacitor. The optimal values of aging time and temperature vary depending on the type and capacitance of the capacitor and the rated voltage and therefore, these are previously determined by performing an experiment. The aging time is usually from several minutes to several days and the aging temperature is usually 300° C. or less by taking account of thermal deterioration of the voltage-applying jig. The aging atmosphere may be air or a gas such as argon, nitrogen and helium and the aging may be performed in any one condition of reduced pressure, atmospheric pressure and applied pressure. When the aging is performed in water vapor or performed after water vapor has been supplied, stabilization of the dielectric layer sometimes proceeds. One example of the method for supplying water vapor is a method of supplying water vapor from a water reservoir placed in the aging furnace by using heat.

The method of applying a voltage can be designed to pass an arbitrary current such as direct current, alternating current having an arbitrary waveform, alternating current superposed on direct current, and pulse current. It is also possible to once stop applying a voltage on the way of aging and again apply a voltage.

The solid electrolytic capacitor produced by the method of the present invention can be preferably used, for example, in a circuit using a high-capacitance and low-ESR capacitor, such as central processing circuit and power source circuit. These circuits can be used in various digital devices such as a personal computer, server, camera, game machine, DVD equipment, Audio-Visual equipment and cellular phone, and electronic devices such as various power sources. The solid electrolytic capacitor produced in the present invention has a high capacitance and a good ESR performance can contribute to production of high-performance electronic circuit and electronic equipment.

### EXAMPLES

The present invention is described in detail below by referring to Examples and Comparative Examples, however, the present invention is not limited thereto.

### Production Example 1

### Preparation of Pyrrole Dimer

40 g of pyrrole (0.2 mol/L) was added to a solvent with a volume ratio 1:4 of water to ethanol in a glass vessel, and 10 mg of anthraquinonesulfonic acid was added thereto per 1 L of the solvent, mixed together and left standing at room temperature for a week. After allowing ethanol to evaporate from the blackened solution, oily matter was taken out of a water layer. Monomers and polymers comprising three or monomer units were removed by liquid column chromatography to thereby obtain 1.5 g of an oily matter (yield 7%). By NMR and mass spectral analysis this oily matter was confirmed to be pyrrole dimer. The amount of the collected monomer was 27 g and the amount of the generated trimer was about 0.3 g.

### Example 1

Sintered bodies of 4.5×1.0×3.1 mm were prepared by using tantalum powder having a CV value (product of capacitance and chemical formation voltage) of 150,000 μF·V/g (sintering temperature: 1310° C., sintering time: 20 minutes, density of the sintered body: 6.1 g/cm³, with tantalum lead wires of 0.40 mmΦ; the tantalum lead wire was partially embedded in each of the sintered bodies, in parallel to the longitudinal direction of 4.5 mm length, with the remaining part of the lead wire protruding from the sintered body to serve as anode part). Each of the sintered bodies to serve as anode, excluding a part of the lead wire, was immersed in a 0.7 mass % of benzoic acid solution, and subjected to chemical formation at 65° C. for 400 minutes by applying 10 V between the anode and a tantalum plate electrode serving as cathode, to thereby form a dielectric oxide film layer comprising Ta₂O₅. Series of the operations of subjecting the sintered body excluding the lead wire alternately to immersion in a tank containing an aqueous 20 mass % sodium molybdate solution followed by drying and to immersion in a tank containing an aqueous 10 mass % sodium borohydride solution followed by drying, and performing chemical reformation at 65° C. with 8 V for 15 minutes in 0.7 mass % of benzoic acid solution, was repeated 10 times, to create electrically defective minute portions in the dielectric layer.

Subsequently, each of the sintered bodies was immersed in a tank (the tank itself was coated with a tantalum foil to serve as an external electrode) containing a mixed solution of 20 mass % of ethylene glycol and water to which solution 2 mass % of naphthalenesulfonic acid and a supersaturating amount of pyrrole dimer prepared in Production Example 1 had been added. By using the lead wire of the sintered body as anode and the external electrode as cathode, an electric current of 120 μA was passed for an hour to thereby form a semiconductor layer on the dielectric layer (the temperature of the electrolytic polymerization is shown in Table 1). The sintered body was pulled out, washed with water, washed with an alcohol, dried, and then subjected to chemical reformation in 0.7 mass % of benzoic acid solution at 65° C., 7 V for 15 minutes. The sintered body was pulled out, washed with water, washed with an alcohol for 15 minutes, and dried. The series of operations of forming a semiconductor layer and chemical reformation was performed 7 times to thereby form a semiconductor layer comprising polypyrrole having as its main dopant naphthalenesulfonate ions. Subsequently, carbon paste was attached onto the semiconductor layer, followed by drying, and then silver paste was laminated thereon, followed by drying, to thereby form an electrode layer. Thus, a plurality of capacitor elements was prepared. On a pair of end parts of a separately-prepared lead frame serving as an external electrode, the lead wire of the sintered body and the silver paste surface of the electrode layer were placed and electrically or mechanically connected by spot-welding for the former and by using the same silver paste for the latter. Thereafter, the entirety excluding a part of the lead flame was transfer-molded with epoxy resin and the lead frame outside the mold was cut at a predetermined position and the remaining frame was bent along the jacket to serve as an external terminal. In this way, chip capacitors having a size of 7.3×4.3×1.8 mm were produced.

### Reference Example 1

Chip capacitors were produced exactly in the same manner as in Example 1 except that pyrrole monomer was used instead of pyrrole dimer.

### Reference Example 2

Chip capacitors were produced exactly in the same manner as in Example 1 except that pyrrole monomer was used instead of pyrrole dimer and that the electrolytic oxidation polymerization temperature was set at 3° C.

### Example 2

Niobium primary powder (average particle diameter: 0.33 μm) pulverized by utilizing the hydrogen embrittlement of a niobium ingot was granulated to thereby obtain niobium powder having average particle diameter of 120 μm (since this powder was fine particulate, the surface was naturally oxidized to contain 105,000 ppm of oxygen as a whole). Next, the powder was left standing in a nitrogen atmosphere at 450° C., and then in argon at 700° C. to become niobium powder partially nitrided to contain a nitrided amount of 9,500 ppm (CV 275,000 μF·V/g). The resulting niobium powder was molded together with a 0.48 mmΦ niobium wire and then sintered at 1260° C. to thereby produce plurality of sintered bodies (conductors) having a size of 4.0×3.5×1.7 mm (mass: 0.08 g. The niobium wire serving as lead wire was present such that 3.7 mm of it was inside the sintered body and 10 mm was outside the sintered body).

Thereafter, each of the sintered bodies was chemically formed in 0.1 mass % anthraquinonesulfonic acid solution at 80° C. and 20V for 7 hours to thereby form a dielectric layer mainly comprising diniobium pentoxide on the surface of the sintered body and a portion of the lead wire. Then, the series of operations of immersing the sintered bodies in an alcohol solution of 20 mass % iron naphthalenesulfonate, followed by drying, and then performing chemical reformation in 30 mass % toluenesulfonic acid solution at 80° C. and 15 V for 15 minutes was repeated 5 times. Electrolytic polymerization of 80 μA was performed at the temperature described in Table 1 for 60 minutes in a mixed solution of water having dissolved therein a trace amount of pyrrole dimer and 1 mass % of anthraquinonesulfonic acid therein and 30 mass % ethylene glycol. The sintered bodies were pulled out from the solution, washed with water and then with alcohol, followed by drying, and then chemical reformation was performed in 1 mass % anthraquinonesulfonic acid solution at 80° C. and 14 V for 15 minutes. The series of the operations of electrolytic polymerization and chemical reformation was repeated 10 times to thereby form a semiconductor layer comprising polypyrrole containing anthraquinonesulfonic acid ion as its main dopant on the dielectric layer.

Next, carbon paste was laminated on the semiconductor layer, followed by drying, and then silver paste was laminated thereon, followed by drying, to thereby form an electrode layer. Thus, a plurality of capacitor elements was prepared. On a pair of end parts of a separately-prepared lead frame serving as an external electrode, the lead wire of the sintered body and the silver paste surface of the electrode layer were placed and electrically or mechanically connected by spot-welding for the former and by using the same silver paste for the latter. Thereafter, the entirety excluding a part of the lead flame was transfer-molded with epoxy resin and the lead frame outside the mold was cut at a predetermined position and the remaining frame was bent along the jacket to serve as an external terminal. In this way, chip capacitors in a size of 7.3×4.3×2.8 mm were produced. Subsequently, each of the capacitor was aged at 125° C. and 7 V for 3 hours and then allowed to pass 3 times through a tunnel furnace in which the peak temperature was 270° C. and the dwelling time in the region of 230° C. was 35 seconds, thereby completing final chip capacitors.

### Reference Example 3

Chip capacitors were produced exactly in the same manner as in Example 2 except that pyrrole monomer was used instead of pyrrole dimer.

### Reference Example 4

Chip capacitors were produced exactly in the same manner as in Example 2 except that pyrrole monomer was used instead of pyrrole dimer and that the electrolytic oxidation polymerization temperature was set at −14° C.

### Reference Example 5

Chip capacitors were produced in exactly the same manner as in Example 2 except that pyrrole trimer obtained as a by-product in Production Example 1 was used instead of pyrrole dimer and that the electrolytic oxidation polymerization temperature was set at 30° C.

### Reference Example 6

Pyrrole tetramer obtained as a by-product in Production Example 1 was used instead of pyrrole dimmer used in Example 2, and electrolytic oxidation polymerization was conducted at 21° C. However, the polymer obtained here could not cover the surface of the dielectric body.

### Test Example

The capacitance and ESR of 30 units of capacitors produced each in the above Examples 1 to 2 and Reference Examples 1 to 5 were measured in the following methods.

### Capacitance of Capacitor:

The capacitance of a capacitor was measured at room temperature and 120 Hz by using an LCR meter manufactured by Hewlett-Packard Development Company, L.P. ESR value:

The equivalent series resistance of each capacitor was measured at 100 kHz. The measurement results (the average value: n=30) are shown in Table 1.

TABLE 1

| | | polymerization | capacitor | capacitor |
|---|---|---|---|---|
| | | temperature | capacitance | ESR |
| | compound | (° C.) | (μF) | 100 kHz (mΩ) |
| Example 1 | pyrrole | 22 | 1120 | 19 |
| | dimer | | | |
| Reference | pyrrole | 22 | 880 | 24 |
| Example 1 | monomer | | | |
| Reference | pyrrole | 3 | 1040 | 19 |
| Example 2 | monomer | | | |
| Example 2 | pyrrole | 30 | 970 | 20 |
| | dimer | | | |
| Reference | pyrrole | 30 | 750 | 32 |
| Example 3 | monomer | | | |
| Reference | pyrrole | −14 | 940 | 19 |
| Example 4 | monomer | | | |
| Reference | pyrrole | 30 | 680 | 190 |
| Example 5 | trimer | | | |
| Reference | pyrrole | 21 | — | — |
| Example 6 | tetramer | | | |

According to the results of Table 1, it is found out that polymerization can proceed smoothly at room temperature when pyrrole dimer is used and that the produced solid electrolytic capacitor has sufficient capacitance and ESR as well as those of the capacitors obtained in Reference Examples 2 (a tantalum capacitor) and 4 (a niobium capacitor) polymerizing a conventional pyrrole monomer at low temperature. When using a trimer, the capacitance is reduced and the ESR is extremely deteriorated (Reference Example 5).

1. A method for producing a solid electrolytic capacitor element, comprising electrolytically oxidation-polymerizing pyrrole dimer to form a semiconductor layer on a conductor having dielectric oxide film thereon.

2. The method for producing a solid electrolytic capacitor element according to claim 1, wherein the semiconductor is an organic semiconductor mainly consisting of polypyrrole doped with a dopant.

3. The method for producing a solid electrolytic capacitor element according to claim 2, wherein the dopant is at least one kind selected from aryl sulfonic acid compounds and salts thereof, alkyl sulfonic acid compounds and salts thereof, various polymeric sulfonic acid compounds and salts thereof and a compound in which each of these sulfonic acid compounds is substituted by various substituents.

4. The method for producing a solid electrolytic capacitor element according to claim 1, wherein the polymerization temperature is within a range of 10 to 40° C.

5. The method for producing a solid electrolytic capacitor element according to claim 1, wherein as the pyrrole dimer, a reaction product isolated from a reaction solution obtained by allowing a solution containing pyrrole and an oxidant in water or a mixed solvent of an organic solvent and water to react at 10 to 100° C. for 1 minute to 1600 hours is used.

6. The method for producing a solid electrolytic capacitor element according to claim 1, wherein the conductor is a metal or alloy consisting mainly of at least one selected from the group consisting of tantalum, niobium, titanium and aluminium, niobium oxide, or a mixture of two or more of these metals, alloys and niobium oxide.

7. The method for producing a solid electrolytic capacitor element according to claim 1, wherein the conductor consists of tantalum having a CV value of 80,000 μF·V/g or more.

8. The method for producing a solid electrolytic capacitor element according to claim 1, wherein the conductor consists of niobium having a CV value of 150,000 μF·V/g or more.

9. The method for producing a solid electrolytic capacitor element according to claim 1, wherein the conductor consists of a sintered body having an anode lead connected thereto.

10. The method for producing a solid electrolytic capacitor element according to claim 9, wherein material of the anode lead is tantalum, aluminium, niobium, titanium, or an alloy mainly consisting of these valve-action metals.

11. The method for producing a solid electrolytic capacitor element according to claim 9, wherein the anode lead is in form of wire, foil or sheet.

12. The method for producing a solid electrolytic capacitor element according to claim 2, wherein electroconductivity of the semiconductor is within a range of 10⁻² to 10³ S/cm.

13. A solid electrolytic capacitor element produced by the method described in claim 1.

14. A solid electrolytic capacitor obtained by encapsulating the solid electrolytic capacitor element described in claim 13 with jacketing resin.

15. An electronic circuit using the solid electrolytic capacitor described in claim 14.

16. An electronic device using the solid electrolytic capacitor described in claim 14.
